(19) United States
(12) Patent Application Publication
(10) Pub. No.: US 2026/0066169 A1
(43) Pub. Date: Mar. 5, 2026

(54) High Resistivity Buffers and Interlayers to Promote BiSb (012) and (001) and Minimized Shunting

(71) Applicant: Western Digital Technologies, Inc., San Jose, CA (US)

(72) Inventors: Quang LE, San Jose, CA (US); Brian R. YORK, San Jose, CA (US); Cherngye HWANG, San Jose, CA (US); Jose ORTEGA, Hollister, CA (US); Xiaoyong LIU, San Jose, CA (US); Son T. LE, San Jose, CA (US); Hisashi TAKANO, Fujisawa-shi, Kanagawa (JP)

(73) Assignee: Western Digital Technologies, Inc., San Jose, CA (US)

(21) Appl. No.: 19/313,050

(22) Filed: Aug. 28, 2025

Related U.S. Application Data
(60) Provisional application No. 63/688,154, filed on Aug. 28, 2024.

(51) Int. Cl. H01F 10/32; G01R 33/09; G11B 5/31; H10B 61/00; H10N 50/10; H10N 50/85

(52) U.S. Cl. CPC H01F 10/3268; G01R 33/098; G11B 5/31; H10B 61/20; H10N 50/10; H10N 50/85

(57) ABSTRACT

The present disclosure generally relates to spintronic material stacks and devices. A spintronic stack comprises an amorphous layer, a texturing layer comprising one or more materials selected from the group consisting of: TaₓW₁₋ₓ, MgO, YPt, RuAl, RuAlN, HfN, NiAlGeN, IrAlGeN, and (TaₓW₁₋ₓ)N, and TiN, where x between 0.005 and 1, a barrier layer comprising one or more materials selected from the group consisting of: NiAlGeN, NiAlGe, IrAlGeN, IrAlGe, HfN, and TiN, a topological insulating (TI) layer comprising BiSb having a (012) or (001) orientation, an interlayer, and a ferromagnetic layer. The texturing layer, the barrier layer, and the interlayer each individually comprises a material having a high resistivity to minimize shunting, act as a migration barrier, and function as a crystal symmetry transfer layer to provide the (012) or (001) orientation to the TI layer. The spintronic stack may be nitrogenated to increase the resistivity of the stack.

### CROSS-REFERENCE TO RELATED APPLICATIONS

This application claims benefit of U.S. provisional patent application Ser. No. 63/688,154, filed Aug. 28, 2024, which is herein incorporated by reference.

### BACKGROUND OF THE DISCLOSURE

### Field of the Disclosure

Embodiments of the present disclosure generally relate to spintronic devices with a textured buffer layer for growing a topological insulator (TI) material.

### Description of the Related Art

Spintronic devices have been used in various sensor, data storage, memory, and logic applications, and have shown promise in recent years to support devices for artificial intelligence applications. Various materials have been attempted in the search for efficient spin Hall effect (SHE) materials for such devices, among which are various topological insulator materials with high spin Hall angles.

BiSb layers are narrow band gap topological insulator material having both giant spin Hall effect and high electrical conductivity. BiSb is a material that has been proposed in various spin-orbit torque (SOT) device applications, such as for a spin Hall layer for magnetoresistive random access memory (MRAM) devices, magnetic recording read heads, sensors, and energy-assisted magnetic recording (EAMR) magnetic recording heads. However, utilizing BiSb materials in commercial SOT applications can present several obstacles. For example, BiSb materials require specific buffer layers and/or interlayers, as well as optimal processing conditions, to achieve the desired orientation.

Therefore, there is a need for an improved SOT device utilizing topological insulating (TI) layer(s) having a desired crystal orientation.

### SUMMARY OF THE DISCLOSURE

The present disclosure generally relates to spintronic material stacks and devices. A spintronic stack comprises an amorphous layer, a texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, a barrier layer comprising one or more materials selected from the group consisting of: X-AlGe, X-AlGeN (where Ge is about 0.5 at. % to about 50 at. % and N is less than about 20 at. %), where X is one of Co, Ni, Ru, Rh, or Ir; and from fcc materials HfN, TiN, TaₓW₁₋ₓN, and TaₓHf₁₋ₓN (for nitrides of Ti, Hf, TaW, and TaHf, the N can be stoichiometric or nonstoichiometric), a topological insulating (TI) layer comprising BiSb having a (012) or (001) orientation, an interlayer, a ferromagnetic layer, and a capping layer. The texturing layer, the barrier layer, and the interlayer each individually comprises a material having a high resistivity to minimize shunting, act as a migration barrier, and function as a crystal symmetry transfer layer to provide the (012) or (001) orientation to the TI layer. The spintronic stack may be nitrogenated to further increase the resistivity of the stack.

In one embodiment, a spintronic stack comprises an amorphous layer, a buffer layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, a topological insulating (TI) layer comprising BiSb having a (012) or (001) orientation, an interlayer, a ferromagnetic layer, and a capping layer.

In another embodiment, a spintronic stack comprises an amorphous layer(s), such as an amorphous metal oxide layer, a metal amorphous layer, or a bilayer of an amorphous metal oxide and amorphous metal layer, a buffer layer disposed on the amorphous layer(s), a buffer layer disposed on the amorphous layer, the buffer layer comprising: a texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, and a barrier layer comprising one or more materials selected from the group consisting of: X-AlGe, X-AlGeN (where Ge is about 0.5 at. % to about 50 at. % and N is less than about 20 at. %), where X is one of Co, Ni, Ru, Rh, or Ir, and from fcc materials HfN, TiN, TaₓW₁₋ₓN, TaₓHf₁₋ₓN (for Nitrides of Ti, Hf, TaW, and TaHf, the N can be stoichiometric or nonstoichiometric), a topological insulating (TI) layer disposed on the barrier layer, the TI layer comprising BiSb having a (012) or (001) orientation, an interlayer disposed on the TI layer, a ferromagnetic layer disposed on the interlayer, and a capping layer.

In yet another embodiment, a spintronic stack comprises an amorphous layer(s), such as an amorphous metal oxide layer, a metal amorphous layer, or a bilayer of an amorphous metal oxide and amorphous metal layer, a buffer layer disposed on the amorphous layer(s), a texturing layer disposed on the amorphous layer, the texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, a ferromagnetic layer disposed on the texturing layer, an interlayer disposed on the ferromagnetic layer, a topological insulating (TI) layer disposed on the interlayer, the TI layer comprising BiSb having a (012) or (001) orientation, and a barrier layer disposed on the TI layer, the barrier layer comprising one or more materials selected from the group consisting of: X-AlGe, X-AlGeN (where Ge is about 0.5 at. % to about 50 at. % and N is less than about 20 at. %), where X is one of Co, Ni, Ru, Rh, or Ir, and from fcc materials HfN, TiN, TaₓW₁₋ₓN, and TaₓHf₁₋ₓN (for Nitrides of Ti, Hf, TaW, and TaHf, the N can be stoichiometric or nonstoichiometric). The interlayer comprises one or more materials selected from the group consisting of: GeN, SiN, AlN, TiN, CrN, ZrN, MgO, MgTiO, MgAlO, TiO, TiN, HfN, X-QGe, X-QGeN, where Ge is from about 0.5 at. % to about 50 at. % and nitrogen is less than about 20 at. %, where X is one of Co, Ni, Ru, Rh, or Ir, Q is one of Al or Fe, and combinations thereof.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic illustration of certain embodiments of a magnetic media drive including a magnetic recording head with a spintronic device.

FIG. 2 is a fragmented, cross-sectional view of certain embodiments of a read/write head with a spintronic device.

FIG. 3 illustrates a forward spintronic stack, according to one embodiment.

FIG. 4 illustrates a reverse spintronic stack, according to another embodiment.

FIG. 5A is a schematic cross-sectional view of a SOT device for use in a MAMR magnetic recording head, such as the MAMR magnetic recording head of the drive of FIG. 1 or other suitable magnetic media drives.

FIGS. 5B-5C are schematic MFS views of certain embodiments of a portion of a MAMR magnetic recording head with a SOT device of FIG. 5A.

FIG. 6 is a schematic cross-sectional view of a SOT MTJ used as a MRAM device.

FIG. 7 illustrates a schematic of a simplified deep neural network (DNN) or logic device, according to one embodiment.

FIG. 8 illustrates a spin orbital-spin orbital (SO-SO) device, according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to spintronic material stacks and devices. A spintronic stack comprises an amorphous layer, a texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is between 0.005 and 1, a barrier layer comprising one or more materials selected from the group consisting of: NiAlGeN, NiAlGe, IrAlGeN, IrAlGe, HfN, and TiN, a topological insulating (TI) layer comprising BiSb having a (012) or (001) orientation, an interlayer, a ferromagnetic layer, and a capping layer. The texturing layer, the barrier layer, and the interlayer each individually comprises a material having a high resistivity to minimize shunting, act as a migration barrier, and function as a crystal symmetry transfer layer to provide the (012) or (001) orientation to the TI layer. The spintronic stack may be nitrogenated to further increase the resistivity of the stack.

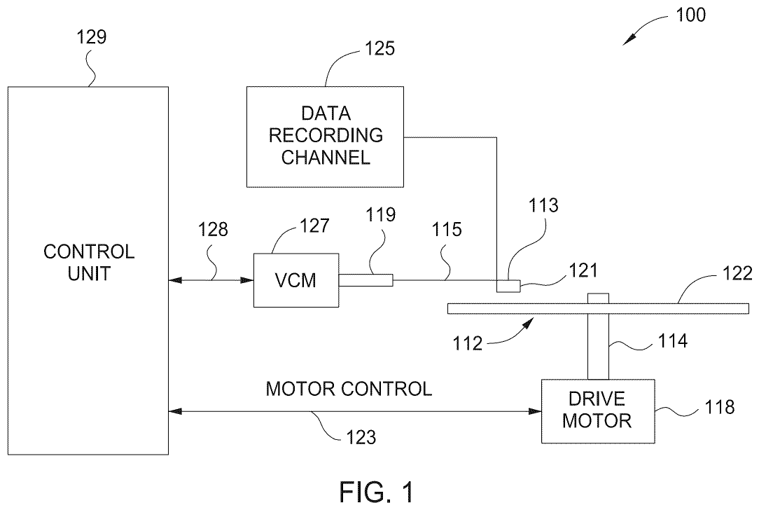

FIG. 1 is a schematic illustration of certain embodiments of a magnetic media drive 100 including a magnetic recording head with a SOT device. Such a magnetic media drive may be a single drive or comprise multiple drives. For illustration, a single disk drive 100 is shown according to certain embodiments. As shown, at least one rotatable magnetic disk 112 is supported on a spindle 114 and rotated by a drive motor 118. The magnetic recording on each magnetic disk 112 is in the form of any suitable patterns of data tracks, such as annular patterns of concentric data tracks (not shown) on the magnetic disk 112.

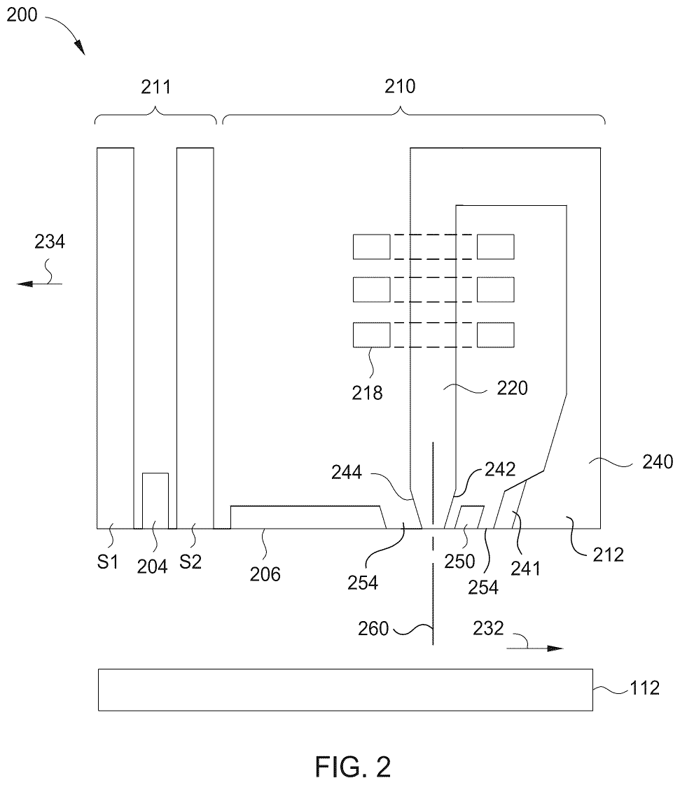

At least one slider 113 is positioned near the magnetic disk 112, and each slider 113 supports one or more magnetic head assemblies 121, including a SOT device. As the magnetic disk 112 rotates, the slider 113 moves radially in and out over the disk surface 122 so that the magnetic head assembly 121 may access different tracks of the magnetic disk 112 where desired data are written. Each slider 113 is attached to an actuator arm 119 by a suspension 115. The suspension 115 provides a slight spring force which biases the slider 113 toward the disk surface 122. Each actuator arm 119 is attached to an actuator means 127. The actuator means 127, as shown in FIG. 2, may be a voice coil motor (VCM). The VCM includes a coil movable within a fixed magnetic field, the direction and speed of the coil movements being controlled by the motor current signals supplied by the control unit 129.

During operation of the disk drive 100, the rotation of the magnetic disk 112 generates an air bearing between the slider 113 and the disk surface 122 which exerts an upward force or lift on the slider 113. The air bearing thus counterbalances the slight spring force of suspension 115, and supports slider 113 off and slightly above the disk surface 122 by a small, substantially constant spacing during regular operation.

The various components of the disk drive 100 are operated by control signals generated by control unit 129, such as access control signals and internal clock signals. The control unit 129 typically comprises logic control circuits, storage means, and a microprocessor. The control unit 129 generates control signals to control various system operations such as drive motor control signals on line 123 and head position and seek control signals on line 128. The control signals on line 128 provide the desired current profiles to move optimally and position slider 113 to the desired data track on disk 112. Write and read signals are communicated to and from write and read heads on the assembly 121 by recording channel 125.

The above description of a typical magnetic media drive and the accompanying illustration of FIG. 1 are for representation purposes only. It should be apparent that magnetic media drives may contain a large number of media, or disks, and actuators, and each actuator may support a number of sliders.

It is to be understood that the embodiments discussed herein are applicable to a data storage device such as a hard disk drive (HDD) as well as a tape drive such as a tape embedded drive (TED) or an insertable tape media drive. An example TED is described in co-pending patent application titled “Tape Embedded Drive,” U.S. application Ser. No. 16/365,034, filed Mar. 31, 2019, assigned to the same assignee of this application, which is herein incorporated by reference. As such, any reference in the detailed description to an HDD or tape drive is merely for exemplification purposes and is not intended to limit the disclosure unless explicitly claimed. For example, references to disk media in an HDD embodiment are provided as examples only, and can be substituted with tape media in a tape drive embodiment. Furthermore, reference to or claims directed to magnetic recording devices or data storage devices are intended to include at least both HDD and tape drive unless HDD or tape drive devices are explicitly claimed.

FIG. 2 is a fragmented, cross-sectional side view of certain embodiments of a read/write head 200 having a SOT device. The read/write head 200 faces a magnetic media 112. The read/write head 200 may correspond to the magnetic head assembly 121 described in FIG. 1. The read/write head 200 includes a media facing surface (MFS) 212, such as a gas bearing surface, facing the disk 112, a write head 210, and a magnetic read head 211. As shown in FIG. 2, the magnetic media 112 moves past the write head 210 in the direction indicated by the arrow 232, and the read/write head 200 moves in the direction indicated by the arrow 234.

In some embodiments, the magnetic read head 211 is a magnetoresistive (MR) read head with an MR sensing element 204 located between MR shields S1 and S2. In other embodiments, the magnetic read head 211 is a magnetic tunnel junction (MTJ) read head that includes an MTJ sensing device 204 disposed between MR shields S1 and S2. The magnetic fields of the adjacent magnetized regions in the magnetic disk 112 are detectable by the MR (or MTJ) sensing element 204 as the recorded bits. The SOT device of various embodiments can be incorporated into the read head 211 as the sensing element. An example of a SOT read head is described in a co-pending patent application titled “Topological Insulator Based Spin Torque Oscillator Reader,” U.S. Pat. No. 11,783,853, issued Oct. 10, 2023, assigned to the same assignee of this application, which is herein incorporated by reference. Another example of a SOT read head is described in co-pending patent applications titled “Non-Localized Spin Valve Reader Hybridized With Spin Orbit Torque Layer,” U.S. application Ser. No. 18/367,877, filed Sep. 13, 2023, and “Non-Localized Spin Valve Multi-Free-Layer Reader Hybridized With Spin Orbit Torque Layers,” U.S. application Ser. No. 18/367,882, filed Sep. 13, 2023, which is herein incorporated by reference.

The write head 210 includes a central or main pole 220, a leading shield 206, a trailing shield 240, an optional spin-orbital torque (SOT) device 250, and a coil 218 that excites the main pole 220. The coil 218 may have a “pancake” structure that winds around a back-contact between the main pole 220 and the trailing shield 240, instead of a “helical” structure shown in FIG. 2. For example, when included, e.g., to achieve a Microwave Assisted Magnetic Recording (MAMR) effect, the SOT device 250 is formed in a gap 254 between the main pole 220 and the trailing shield 240. In certain embodiments, the read/write head 200 additionally includes mechanisms (not shown) for supporting Heat Assisted Magnetic Recording (HAMR), which may include a waveguide coupled to a light source and a near field transducer (NFT) placed adjacent to the main pole 220 and coupled to the waveguide to convert the delivered light into a heating spot on the media.

The main pole 220 includes a trailing taper 242 and a leading taper 244. The trailing taper 242 extends from a location recessed from the MFS 212 to the MFS 212. The leading taper 244 extends from a location recessed from the MFS 212 to the MFS 212. The trailing taper 242 and the leading taper 244 may have the same degree of taper, and the degree of taper is measured with respect to a longitudinal axis 260 of the main pole 220. In some embodiments, the main pole 220 does not include the trailing taper 242 and the leading taper 244. Instead, the main pole 220 includes a trailing side (not shown) and a leading side (not shown), and the trailing side and the leading side are substantially parallel. The main pole 220 may be a magnetic material, such as a FeCo alloy. The leading shield 206 and the trailing shield 240 may comprise magnetic materials, such as a NiFe alloy.

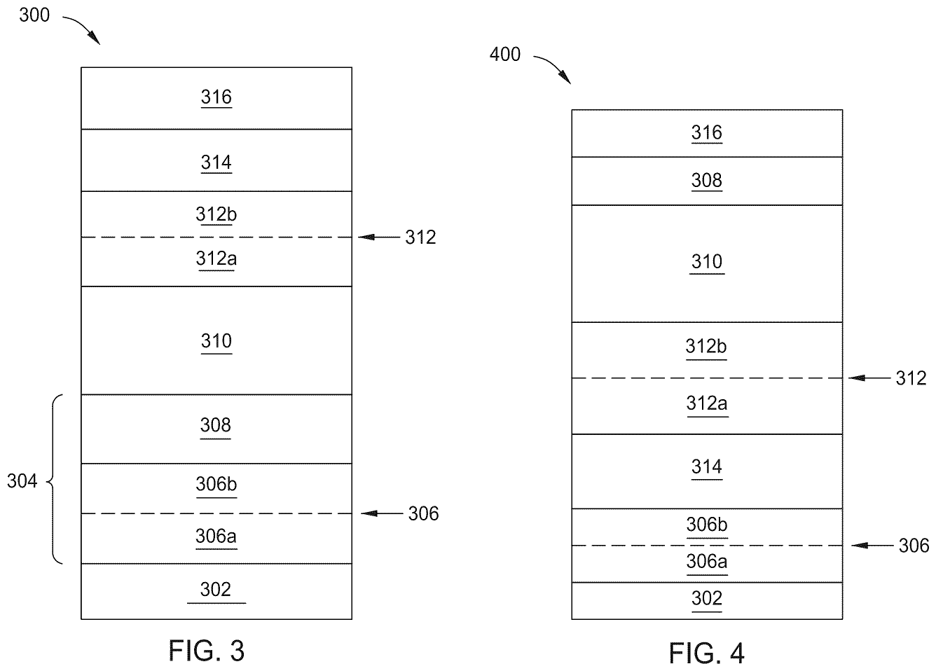

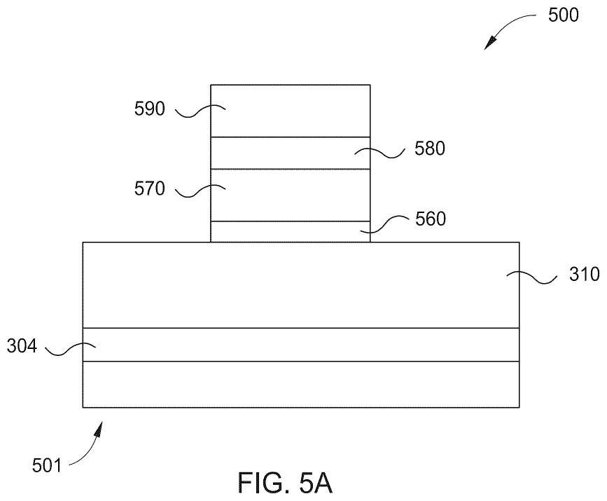

FIG. 3 is a schematic illustration of a forward spintronic material stack 300, according one embodiment. FIG. 4 is a schematic illustration of a reverse spintronic material stack 400, according another embodiment. Each spintronic stack 300, 400 may be utilized in the magnetic media drive 100 of FIG. 1, in the reader, and/or writer portions of the head 200 of FIG. 2, or other suitable magnetic media drives. Each spintronic stack 300, 400 may be utilized in a magnetic memory (such as MRAM) cell or a logic cell. Aspects of the spintronic stacks 300, 400 may be used in combination with one another.

The spintronic stack 300 of FIG. 3 comprises an amorphous layer 302, a buffer layer 304 disposed over the amorphous layer 302, a topological insulator (TI) layer 310 disposed over the buffer layer 304, an interlayer 312 disposed over the TI layer 310, a ferromagnetic (FM) layer 314 disposed over the interlayer 312, and a cap layer 316 disposed on the FM layer 314. The TI layer 310 may be referred to herein as a spin orbit torque (SOT) layer 310. While not shown, the amorphous layer 302 may be disposed on a seed layer. The buffer layer 304 comprises a texturing layer 306 disposed on the amorphous layer 302, and a barrier layer 308 disposed on the texturing layer 306. The buffer layer 304 and the interlayer 312 each individually comprises high resistivity materials.

In some embodiments, the texturing layer 306 comprises one or more sublayers 306a, 306b. The one or more sublayers 306a, 306b are optional, and the texturing layer 306 may be one layer. While two sublayers 306a, 306b are shown, the texturing layer 306 may comprise more than two sublayers. In another embodiment, the barrier layer 308 may comprise one or more sublayers (not shown). In some embodiments, the interlayer 312 comprises one or more sublayers 312a, 312b. While two are shown, the interlayer 312 may comprise more than two sublayers.

The spintronic stack 400 of FIG. 4 is similar to the spintronic stack 300 of FIG. 3; however, the layers of the spintronic stack 400 are ordered differently. The spintronic stack 400 comprises the amorphous layer 302, the texturing layer 306 disposed on the amorphous layer 302, the FM layer 314 disposed on the texturing layer 306, the interlayer 312 disposed on the FM layer 314, the TI layer 310 disposed on the interlayer 312, the barrier layer 308 disposed on the TI layer 310, and the cap layer 316 disposed on the barrier layer 308. The texturing layer 306 and the barrier layer 308 collectively form the buffer layer 304; however, the buffer layer 304 is split into two layers that are spaced apart.

The texturing layer 306, the barrier layer 308, and the interlayer 312 help minimize shunting, act as migration barriers, and function as crystal symmetry transfer layers to promote or provide the (012) or (001) orientation to the TI layer 310.

Each spintronic stack 300, 400 may be nitrogenated upon the layers being deposited. In such an embodiment, each layer of the spintronic stack 300, 400 comprises a small amount of nitrogen, such as about 0.5 at. % to about 55 at. %. Nitrogenating the spintronic stacks 300, 400 increases the resistivity of the overall spintronic stacks 300, 400.

The amorphous layer 302 comprises NiTa NiW, NiFeTa, NiFeW, CoFeTa, or NiFeGe, IrAlGe, plus Nitrogenated forms of these materials, which may have a high resistance property. In some embodiments, the amorphous layer 302 comprises CoFeTaN. The amorphous layer 302 may be one or more layers, such as an amorphous metal oxide layer, or metal amorphous layer, or a bilayer of an amorphous metal oxide and amorphous metal layer, a buffer layer disposed on the amorphous layer(s). The amorphous layer 302 has a thickness in y-direction of about 10 Å to about 50 Å. The TI layer 310 comprises BiSb having a (012) orientation or a (001) orientation. In some embodiments, the TI layer 310 comprises BiSbX, where X is a dopant. The BiSb layer may be BiSbN when a spintronic stack 300, 400 has been nitrogenated. The TI layer 310 has a thickness in the y-direction of about 50 Å to about 200 Å.

The texturing layer 306 comprises one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN In embodiments where the texturing layer 306 comprises one or more sublayers 306a, 306b, the first sublayer 306a may comprise MgO, TaW₃, TaW₃N, or YPt, and the second sublayer 306b may comprise RuAlN, HfN, NiAlGeN, IrAlGeN, TaₓW₁₋ₓN, or TaₓW₁₋ₓ, where x is between 0.005 and 1. For example, when the first sublayer 306a comprises MgO, the second sublayer 306b may comprise TaW₃ or RuAlN, and when the first sublayer 306a comprises YPt or TaW₃, the second sublayer 306b may comprise HfN. The texturing layer 306 has a total thickness in the y-direction of about 30 Å to about 120 Å.

The barrier layer 308 comprises one or more materials selected from the group consisting of: X-AlGe, X-AlGeN (where Ge is about 0.5 at. % to about 50 at. % and N is less than about 20 at. %), where X is one of Co, Ni, Ru, Rh, or Ir, HfN, TiN, TaₓW₁₋ₓN, and TaₓHf₁₋ₓN, where x is from 0.005 to 1. In one embodiment, the barrier layer 308 comprises a first sublayer of HfN, and a second sublayer of TiN, or a first sublayer comprising MgO, and a second sublayer comprising NiGeAlN or IrAlGeN. The barrier layer 308 has a total thickness in the y-direction of about 3 Å to about 30 Å. When materials are written in the form of “X-Q”, the dash (-) indicates the material is an alloy.

The interlayer 312 comprises one or more materials selected from the group consisting of: X-QGe, X-QGeN, where X is one of Co, Ni, Ru, Rh, or Ir, Q is one of Al or Fe, GeN, SiN, AlN, TiN, CrN, ZrN, MgO, MgTiO, MgAlO, TiO, TiN, HfN, and combinations thereof. For example, when the first sublayer 312a comprises NiFeGe. IrAlGeN, IrAlGe, or NiFeGeN, the second sublayer 312b may comprise MgO, HfN, or Ta₃WN, or when the first sublayer 312a comprises GeN, the second sublayer 312b may comprise IrAlGeN, IrAlGe, NiAlGe, or NiAlGeN. The interlayer has a thickness in the y-direction of about 3 Å to about 20 Å.

The FM layer 314 comprises CoFeB, CoFeBN, NiFe, CoFeNiN, CoFeN, CoFeHf, or other suitable ferromagnetic materials or alloys. The cap layer 316 can be multiple layers comprising: (1) a material selected from the group consisting of high resistance amorphous SiN, Al₂O₃, SiO₂, NiFeTa, NiTa, NiW, NiFeW, NiFeGe, HfN, GeN, and NiFeGeN, or (2) high resistance crystalline ceramic materials, such as TiO, MgO, MgTiO layers, or (3) lower resistance transition heavy metals and alloys thereof comprising one or more of Pt, Co, Cu, Ni, Ru, Ta, Cr, Au, and Rh, if such transition heavy metals and alloys are used in combination with higher resistance cap layer material options specified in (1) and/or (2), other non-magnetic materials, or combinations thereof.

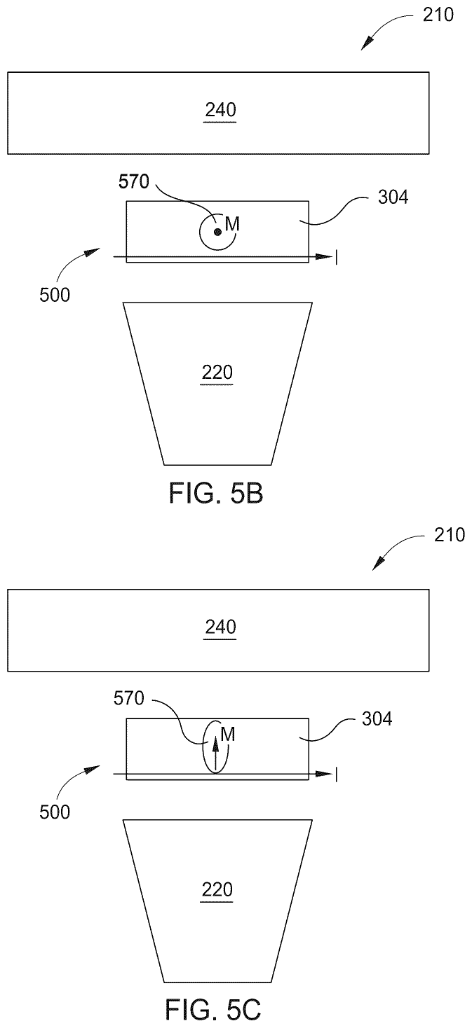

FIG. 5A is a schematic cross-sectional view of a based spin orbit torque (SOT) device 500 for use in a MAMR magnetic recording head, such as the MAMR magnetic recording head of the drive 100 of FIG. 1 or other suitable magnetic media drives. The SOT device 500 comprises a TI layer 310 orientation formed over a buffer layer 304 formed over a substrate 501, such as the TI layer 310 and the buffer layer 304 of FIGS. 3-4. Thus, the TI layer 310 may comprise BiSb having a (012) or (001) orientation. In some embodiments, the buffer layer 304 is the interlayer 312 of FIGS. 3-4. A spin torque layer (STL) 570 is formed over the TI layer 310. The STL 570 comprises a ferromagnetic material such as one or more layers of CoFe, CoIr, NiFe, and CoFeX alloy wherein X=B, Ta, Re, or Ir. The STL 570 may correspond to the FM layer 314 of the earlier figures.

In certain embodiments, an electrical current shunt block layer 560 is disposed between the TI layer 310 and the STL 570. The electrical current shunt blocking layer 560 reduces electrical current from flowing from the TI layer 310 to the STL 570 but allows spin orbital coupling of the TI layer 310 and the STL 570. In certain embodiments, the electrical current shunt blocking layer 560 comprises a magnetic material that provides greater spin orbital coupling between the TI layer 310 and the STL 570 than a nonmagnetic material. In certain embodiments, the electrical current shunt blocking layer 560 comprises a magnetic material of FeCo, FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof in which M is one or more of B, Si, P, Al, Hf, Zr, Nb, Ti, Ta, Mo, Mg, Y, Cu, Cr, and Ni. Me is one or more of Si, Al, Hf, Zr, Nb, Ti, Ta, Mg, Y, or Cr. In certain embodiments, the electrical current shunt blocking layer 560 is formed to a thickness from about 10 Å to about 100 Å. In certain aspects, an electrical current shunt blocking layer 560 with a thickness of over 100 Å may reduce the spin-orbital coupling of the TI layer 310 and the STL 570. In certain aspects, an electrical current shunt blocking layer having a thickness of less than 10 Å may not sufficiently reduce electrical current from TI layer 310 to the STL 570.

In certain embodiments, additional layers are formed over the STL 570 such as a spacer layer 580 and a pinning layer 590. The pinning layer 590 can partially pin the STL 570. The pinning layer 590 comprises a single or multiple layers of PtMn, NiMn, IrMn, IrMnCr, CrMnPt, FeMn, other antiferromagnetic materials, or combinations thereof. The spacer layer 580 comprises single or multiple layers of magnesium oxide, aluminum oxide, other nonmagnetic materials, or combinations thereof.

FIGS. 5B-5C are schematic MFS views of certain embodiments of a portion of a MAMR magnetic recording head 210 with a SOT device 500 of FIG. 5A. The MAMR magnetic recording head 210 can be the magnetic recording head FIG. 2 or other suitable magnetic recording heads in the drive 100 of FIG. 1 or other suitable magnetic media drives such as tape drives. The MAMR magnetic recording head 210 includes a main pole 220 and a trailing shield 240 in a track direction. The SOT device 500 is disposed in a gap between the main pole and the trailing shield 240.

During operation, charge current through a TI layer 310 acting as a spin Hall layer generates a spin current in the BiSb layer. The spin orbital coupling of the BiSb layer and a spin torque layer (STL) 570 causes switching or precession of magnetization of the STL 570 by the spin orbital coupling of the spin current from the TI layer 310. Switching or precession of the magnetization of the STL 570 can generate an assisting AC field to the write field. Energy-assisted magnetic recording heads based on SOT have multiple times greater power efficiency than MAMR magnetic recording heads based on spin transfer torque. As shown in FIG. 5B, an easy axis of a magnetization direction of the STL 570 is perpendicular to the MFS from shape anisotropy of the STL 570, from the pinning layer 590 of FIG. 5A, and/or from hard bias elements proximate to the STL 570. As shown in FIG. 5C, an easy axis of a magnetization direction of the STL 570 is parallel to the MFS from shape anisotropy of the STL 570, from the pinning layer 590 of FIG. 5A, and/or from complex bias elements proximate to the STL 570.

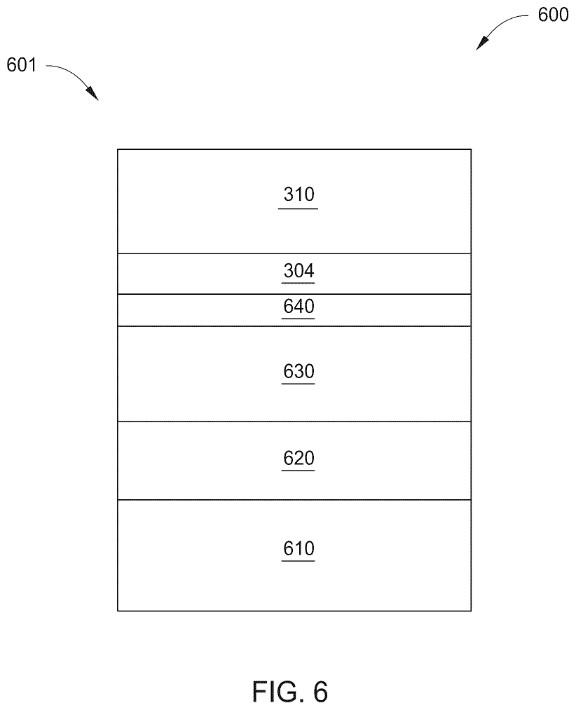

FIG. 6 is a schematic cross-sectional view of an SOT MTJ 601 used as a MRAM device 600. The MRAM device 600 comprises a reference layer (RL) 610, a spacer layer 620 over the RL 610, a recording layer 630 over the spacer layer 620, a buffer layer 304 over an electrical current shunt block layer 640 over the recording layer 630, and a TI layer 310 over the buffer layer 304. The TI layer 310 and the buffer layer 304 may be the TI layer 310 and the buffer layer 304 of FIGS. 3-4. The RL 610 may be the FM layer 314 of those figures. Thus, the TI layer 310 may comprise BiSb having a (012) or (001) orientation.

The RL 610 comprises single or multiple layers of CoFe, CoFeB, other ferromagnetic materials, and combinations thereof. The spacer layer 620 comprises single or multiple layers of magnesium oxide, aluminum oxide, other dielectric materials, or combinations thereof. The recording layer 630 comprises single or multiple layers of CoFe, NiFe, CoFeB, other ferromagnetic materials, or combinations thereof.

As noted above, in certain embodiments, the electrical current shunt block layer 640 is disposed between the buffer layer 304 and the recording layer 630. The electrical current shunt blocking layer 640 reduces electrical current from flowing from the TI layer 310 to the recording layer 630. The electrical current shunt blocking layer 640 still allows spin orbital coupling of the TI layer 310 and the recording layer 630. For example, writing to the MRAM device can be enabled by the spin orbital coupling of the TI layer and the recording layer 630, which allows switching of magnetization of the recording layer 630 by the spin orbital coupling of the spin current from the TI layer 310. In certain embodiments, the electrical current shunt blocking layer 640 comprises a magnetic material that provides greater spin orbital coupling between the TI layer 310 and the recording layer 630 than a nonmagnetic material. In certain embodiments, the electrical current shunt blocking layer 640 comprises a magnetic material of FeCoM, FeCoMO, FeCoMMeO, FeCoM/MeO stack, FeCoMNiMnMgZnFeO, FeCoM/NiMnMgZnFeO stack, multiple layers/stacks thereof, or combinations thereof, in which M is one or more of B, Si, P, Al, Hf, Zr, Nb, Ti, Ta, Mo, Mg, Y, Cu, Cr, and Ni; and Me is Si, Al, Hf, Zr, Nb, Ti, Ta, Mg, Y, or Cr.

The MRAM device 600 of FIG. 6 may include other layers, such as pinning layers, pinning structures (e.g., a synthetic antiferromagnetic (SAF) pinned structure), electrodes, gates, and other structures. Other MRAM devices besides the structure of FIG. 6 can be formed utilizing a TI layer 310 over a buffer layer 304 to form a SOT MTJ 601. For example, additional SOT-based MRAM devices utilizing the various materials and structures disclosed here can be made in accordance with the embodiments described in co-pending application “Buffer Layers to Grow BiSb and YPtBi to Match the Crystal Symmetry of Interlayers and Ferromagnetic layers to Generate Spin-Polarized Current,” U.S. patent application Ser. No. 19/041,211, filed Jan. 30, 2025, the disclosures of which are hereby incorporated by reference.

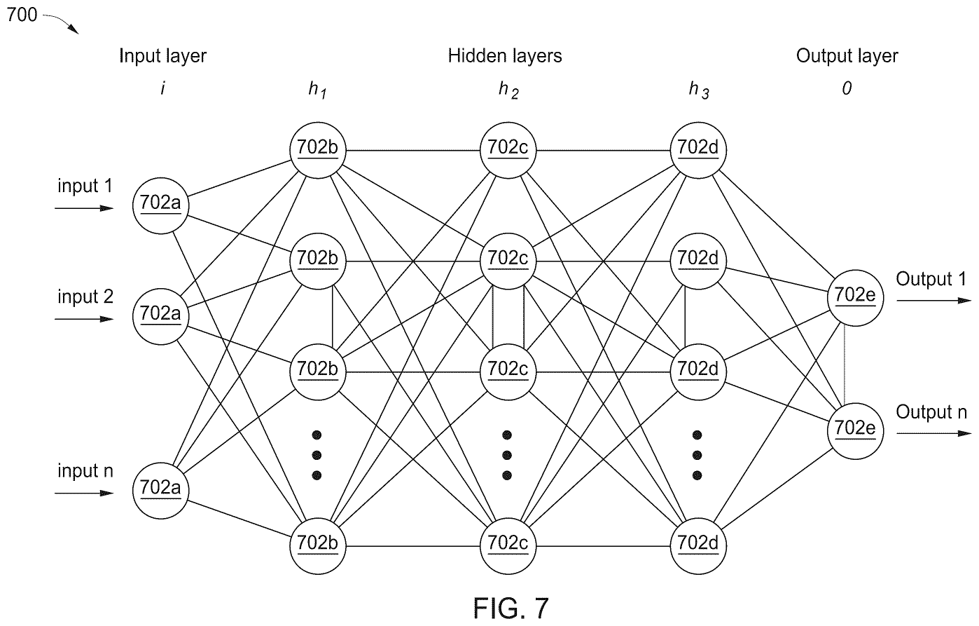

FIG. 7 illustrates a schematic of a simplified deep neural network (DNN) or logic cell 700, according to one embodiment. The DNN 700 comprises a plurality of cells or neural nodes 702a, 702b, 702c, 702d, 702e (collectively referred to herein as neural nodes 702). Each neural node 702 comprises a plurality of spin orbital-spin orbital (SO-SO) cells, where each SO-SO cell is a three-terminal device, comprising a control or weight, an input, and an output. Each SO-SO cell may comprise one or more of the spintronic stacks 300, 400 of FIGS. 3-4. An input current (input 1, input 2, input n) is applied to a first input layer (i) of neural nodes 702a and multiplied by the control or weight.

The output of each neural node 702a of the input layer is then output to each neural node 702b in a first hidden layer (h1) of the DNN 700 as the input for each neural node 702b, where each received input at each neural node 702b is then multiplied by a respective weight for the respective input of each neural node 702b. A weight may conceptually represent a strength of the connection between a neural node in one layer (e.g., neural node 702a) and another neural node in the next layer (e.g., neural node 702b). The results of the multiplications are collectively summed together and sent to a non-linear activation function (not shown here), such as a step or a rectified linear unit (ReLU) function, which determines the final output for that neural node 702b. This multiplication, summation and activation function sequence of processes is then repeated in the various layers h2, h3, etc. throughout the DNN. While three hidden layers are shown, the DNN 700 may comprise any number of hidden layers. Finally, the output of the last hidden layer (here, the third hidden layer) is output to output neural nodes 702e of an output layer (o) as a final result.

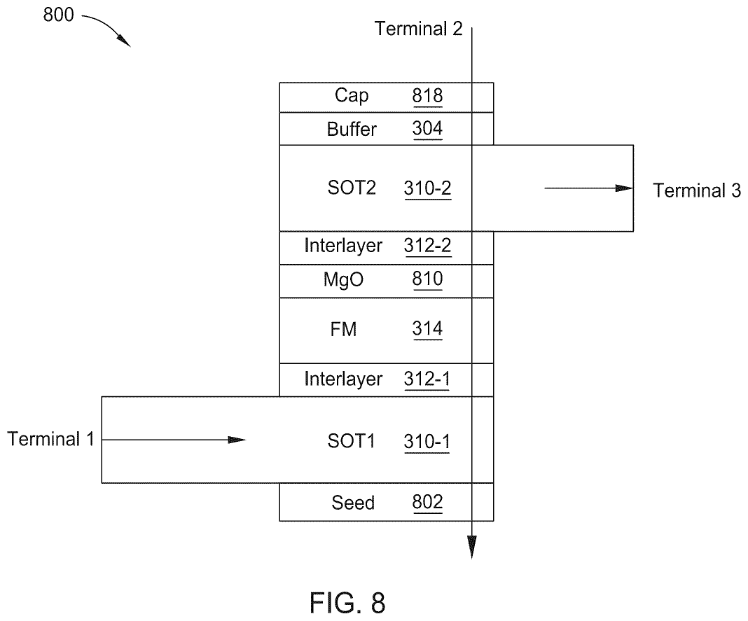

FIG. 8 illustrates a spin orbital-spin orbital (SO-SO) device 800, according to one embodiment. The SO-SO device 800 may be utilized within the DNN 700 of FIG. 7, such as a SO-SO cell. The various layers of the SO-SO device 800 are not drawn to scale, and are intended for illustrative purposes only. The SO-SO devices may be referred to herein as SOT devices. A plurality of SO-SO devices 800 may be configured to function as a neural node 102 of FIG. 7. Thus, a collection of SO-SO devices may be configured to represent a layer (i, h1, h2, h3, o) of the DNN of FIG. 7.

In some embodiments, the SO-SO device 800 comprises a seed layer 802, a first spin orbit torque (SOT) layer 310-1 (SOT1) disposed on the seed layer 802, a first interlayer 312-1 disposed on the first SOT layer 310-1, a ferromagnetic (FM) layer 314 disposed on the first interlayer 312-1, an oxide layer 810 (e.g., an MgO layer) disposed on the FM layer 314, a second interlayer 312-2 disposed on the oxide layer 810, a second SOT layer 310-2 (SOT2) disposed on the second interlayer 312-2, a buffer layer 304 disposed on the second SOT layer 312-2, and a cap layer 818 disposed on the buffer layer 304. The oxide layer 810 may comprise other materials, such as oxides of Ti, V, Cr, Mn, Fe, Ni, Zr, nitrides of Sc, Ti, V, Cr, Fe, Zr, Ta, Hf, W, carbides of Sc, Ti, V, Zr, Ta, Hf, W, and alloy combinations thereof.

The first and second interlayers 312-1, 312-2 may each individually be the interlayer 312 of FIGS. 3-4. The buffer layer 304 may be the buffer layer 304 of FIGS. 3-4. The SOT1 310-1 and the SOT2 310-2 may each individually be the SOT layer 310 of FIGS. 3-4. The FM layer 314 may be the FM layer 314 of FIGS. 3-4.

In some embodiments, the SO-SO device 800 comprises three terminals or interconnects. The first SOT layer 310-1 is coupled to an interconnect or terminal 1. The second SOT layer 310-2 is coupled to an interconnect or terminal 3, where the interconnect or terminal 3 is coupled to the first SOT layer 310-1 of a second SO-SO device via terminal 1. An input current is applied to terminal 2 (representing an input Xₙ current to a neural node) and it flows out-of-plan (current-perpendicular-to-plane (CPP)) through the whole stack toward the seed layer 802. The arrows associated with the terminals indicate the direction of current flows, according to some embodiments. The interconnects or terminals serves as connection points for joining two or more SO-SO devices. Thus, multiple SO-SO devices 800 can be arranged to build out various circuits.

By including high resistivity texturing, barrier and interlayers in a spintronic stack, the texturing layer, barrier layer, and interlayer minimize shunting, act as migration barriers, and function as crystal symmetry transfer layers to promote or provide the (012) or (001) orientation to the TI layer. Moreover, nitrogenating the spintronic stack further increases the resistivity of the stack without changing the initial properties of the various layers of the stack.

In one embodiment, a spintronic stack comprises an amorphous layer, a buffer layer comprising one or more materials selected from the group consisting of: MgO, Ru, Ti, TiN, HfN, YPt, B2 alloys of X-Al, where X is one of Co, Ni, Ru, Rh or Ir, CrMo, TaₓW₁₋ₓN, TaₓHf₁₋ₓN, and TaₓW₁₋ₓ, where x is from 0.005 to 1, a topological insulating (TI) layer comprising BiSb having a (012) or (001) orientation, an interlayer, and a ferromagnetic layer.

The buffer layer comprises a texturing layer and a barrier layer. The texturing layer comprises one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is from 0.005 to 1, and wherein the barrier layer comprises one or more materials selected from the group consisting of: X-AlGe, X-AlGeN (where Ge is about 0.5 at. % to about 50 at. % and N is less than about 20 at. %), where X is one of Co, Ni, Ru, Rh, or Ir, HfN, TiN, TaₓW₁₋ₓN, and TaₓHf₁₋ₓN, where x is from 0.005 to 1. The texturing layer is disposed on the amorphous layer, the ferromagnetic layer is disposed on the texturing layer, the interlayer is disposed on the ferromagnetic layer, the TI layer is disposed on the interlayer, and the barrier layer is disposed on the TI layer. The buffer layer is disposed on the amorphous layer, the TI layer is disposed on the buffer layer, the interlayer is disposed on the TI layer, and the ferromagnetic layer is disposed on the interlayer. The interlayer comprises one or more materials selected from the group consisting of: GeN, SiN, AlN, MgO, HfN, TaₓW₁₋ₓN, NiAlGeN, NiAlGe, IrAlGeN, IrAlGe, and TiN, and wherein the amorphous layer comprises CoFeTaN. Each of the amorphous layer, the buffer layer, the TI layer, the interlayer, and the ferromagnetic layer comprises nitrogen. A memory cell comprises the spintronic stack. A logic cell comprises the spintronic stack. A magnetic sensor comprises the spintronic stack. A magnetic recording device comprises the spintronic stack.

In another embodiment, a spintronic stack comprises an amorphous layer, a buffer layer disposed on the amorphous layer, the buffer layer comprising: a texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is from 0 to 1, and a barrier layer comprising one or more materials selected from the group consisting of: MgO, Ru, Ti, TiN, HfN, YPt, B2 alloys of X-Al, where X is one of Co, Ni, Ru, Rh, or Ir, CrMo, TaₓW₁₋ₓN, TaₓHf₁₋ₓN, and TaₓW₁₋ₓ, where x is from 0.005 to 1, a topological insulating (TI) layer disposed on the barrier layer, the TI layer comprising BiSb having a (012) or (001) orientation, an interlayer disposed on the TI layer, and a ferromagnetic layer disposed on the interlayer.

Each of the amorphous layer, the buffer layer, the TI layer, the interlayer, and the ferromagnetic layer comprises nitrogen. The interlayer comprises one or more materials selected from the group consisting of: GeN, SiN, AlN, IrAlGeN, IrAlGe, MgO, HfN, Ta₃WN, NiAlGeN, NiAlGe, and TiN. The amorphous layer comprises CoFeTaN. A memory cell comprises the spintronic stack. A logic cell comprises the spintronic stack. A magnetic sensor comprises the spintronic stack. A magnetic recording device comprises the spintronic stack.

In yet another embodiment, a spintronic stack comprises an amorphous layer, a texturing layer disposed on the amorphous layer, the texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is from 0 to 1, a ferromagnetic layer disposed on the texturing layer, an interlayer disposed on the ferromagnetic layer, a topological insulating (TI) layer disposed on the interlayer, the TI layer comprising BiSb having a (012) or (001) orientation, and a barrier layer disposed on the TI layer, the barrier layer comprising one or more materials selected from the group consisting of: MgO, Ru, Ti, TiN, HfN, YPt, B2 alloys of X-Al, where X is one of Co, Ni, Ru, Rh or Ir, CrMo, TaₓW₁₋ₓN, TaₓHf₁₋ₓN, and TaₓW₁₋ₓ, where x is from 0.005 to 1.

Each of the amorphous layer, the texturing layer, the TI layer, the interlayer, the barrier layer, and the ferromagnetic layer comprises nitrogen. The texturing layer comprises one or more sublayers, and wherein the amorphous layer comprises CoFeTaN. The interlayer comprises one or more sublayers, and wherein the interlayer comprises one or more materials selected from the group consisting of: X-QGe, X-QGeN, where X is one of Co, Ni, Ru, Rh, or Ir, Q is one of Al or Fe, GeN, SiN, AlN, TiN, CrN, ZrN, MgO, MgTiO, MgAlO, TiO, TiN, HfN, and combinations thereof. A memory cell comprises the spintronic stack. A logic cell comprises the spintronic stack. A magnetic sensor comprises the spintronic stack. A magnetic recording device comprises the spintronic stack.

While the foregoing is directed to embodiments of the present disclosure, other and further embodiments of the disclosure may be devised without departing from the basic scope thereof, and the scope thereof is determined by the claims that follow.

What is claimed is:

1. A spintronic stack, comprising:
an amorphous layer;
a buffer layer comprising one or more materials selected from the group consisting of: MgO, Ru, Ti, TiN, HfN, YPt, B2 alloys of X-Al, where X is one of Co, Ni, Ru, Rh or Ir, CrMo, TaₓW₁₋ₓN, TaₓHf₁₋ₓN, and TaₓW₁₋ₓ, where x is from 0.005 to 1;
a topological insulating (TI) layer comprising BiSb having a (012) or (001) orientation;
an interlayer; and
a ferromagnetic layer.

2. The spintronic stack of claim 1, wherein the buffer layer comprises a texturing layer and a barrier layer.

3. The spintronic stack of claim 2, wherein the texturing layer comprises one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is from 0.005 to 1, and wherein the barrier layer comprises one or more materials selected from the group consisting of: HfN, TiN, X-AlGe, X-AlGeN, where X is one of Co, Ni, Ru, Rh, or Ir, TaₓW₁₋ₓN, and TaₓHf₁₋ₓN, where x is from 0 to 1.

4. The spintronic stack of claim 2, wherein the texturing layer is disposed on the amorphous layer, the ferromagnetic layer is disposed on the texturing layer, the interlayer is disposed on the ferromagnetic layer, the TI layer is disposed on the interlayer, and the barrier layer is disposed on the TI layer.

5. The spintronic stack of claim 1, wherein the buffer layer is disposed on the amorphous layer, the TI layer is disposed on the buffer layer, the interlayer is disposed on the TI layer, and the ferromagnetic layer is disposed on the interlayer.

6. The spintronic stack of claim 1, wherein the interlayer comprises one or more materials selected from the group consisting of: GeN, SiN, AlN, IrAlGeN, IrAlGe, MgO, HfN, Ta₃WN, NiAlGeN, NiAlGe, and TiN, and wherein the amorphous layer comprises CoFeTaN.

7. The spintronic stack of claim 1, wherein each of the amorphous layer, the buffer layer, the TI layer, the interlayer, and the ferromagnetic layer comprises nitrogen.

8. A memory cell comprising the spintronic stack of claim 1.

9. A logic cell comprising the spintronic stack of claim 1.

10. A magnetic sensor comprising the spintronic stack of claim 1.

11. A magnetic recording device comprising the spintronic stack of claim 1.

12. A spintronic stack, comprising:
an amorphous layer;
a buffer layer disposed on the amorphous layer, the buffer layer comprising:
a texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %); TaₓW₁₋ₓ N; HfN; and fcc TaₓHf₁₋ₓN, where x is from 0.005 to 1; and
a barrier layer comprising one or more materials selected from the group consisting of: MgO, Ru, Ti, TiN, HfN, YPt, B2 alloys of X-Al, where X is one of Co, Ni, Ru, Rh or Ir, CrMo, TaₓW₁₋ₓN, TaₓHf₁₋ₓN, and TaₓW₁₋ₓ, where x is from 0.005 to 1;
a topological insulating (TI) layer disposed on the barrier layer, the TI layer comprising BiSb having a (012) or (001) orientation;
an interlayer disposed on the TI layer; and
a ferromagnetic layer disposed on the interlayer.

13. The spintronic stack of claim 12, wherein each of the amorphous layer, the buffer layer, the TI layer, the interlayer, and the ferromagnetic layer comprises nitrogen.

14. The spintronic stack of claim 12, wherein the interlayer comprises one or more materials selected from the group consisting of: GeN, SiN, AlN, IrAlGeN, IrAlGe, MgO, HfN, TaₓW₁₋ₓN, NiAlGeN, NiAlGe, and TiN, where x is between 0.005 and 1.

15. The spintronic stack of claim 12, wherein the amorphous layer comprises CoFeTaN.

16. A memory cell comprising the spintronic stack of claim 12.

17. A logic cell comprising the spintronic stack of claim 12.

18. A magnetic sensor comprising the spintronic stack of claim 12.

19. A magnetic recording device comprising the spintronic stack of claim 12.

20. A spintronic stack, comprising:
an amorphous layer;
a texturing layer disposed on the amorphous layer, the texturing layer comprising one or more materials selected from the group consisting of: TaₓW₁₋ₓ, where x is from 0.005 to 1; MgO; Ru; Ti; TiN; YPt; B2 alloys of X-Al, where X is one of Co, Ni, Ru, Rh, or Ir; Ru-Z, where Z is selected from the group consisting of: Ti, Ta, Zr, and Hf; CrMo (where Mo is between about 20 at. % to about 50 at. %);
TaₓW₁₋ₓ N; HfN; and fcc TaₓHf₁₋ₓN, where x is from 0.005 to 1;
a ferromagnetic layer disposed on the texturing layer;
an interlayer disposed on the ferromagnetic layer;
a topological insulating (TI) layer disposed on the interlayer, the TI layer comprising BiSb having a (012) or (001) orientation; and
a barrier layer disposed on the TI layer, the barrier layer comprising one or more materials selected from the group consisting of: MgO, Ru, Ti, TiN, HfN, YPt, B2 alloys of X-Al, where X is one of Co, Ni, Ru, Rh, or Ir, CrMo, TaₓW₁₋ₓN, TaₓHf₁₋ₓN, and TaₓW₁₋ₓ, where x is from 0.005 to 1.

21. The spintronic stack of claim 20, wherein each of the amorphous layer, the texturing layer, the TI layer, the interlayer, the barrier layer, and the ferromagnetic layer comprises nitrogen.

22. The spintronic stack of claim 20, wherein the texturing layer comprises one or more sublayers, and wherein the amorphous layer comprises CoFeTaN.

23. The spintronic stack of claim 20, wherein the interlayer comprises one or more sublayers, and wherein the interlayer comprises one or more materials selected from the group consisting of: X-QGe, X-QGeN, where X is one of Co, Ni, Ru, Rh, or Ir, Q is one of Al or Fe, GeN, SiN, AlN, TiN, CrN, ZrN, MgO, MgTiO, MgAlO, TiO, TiN, HfN, and combinations thereof.

24. A memory cell comprising the spintronic stack of claim 20.

25. A logic cell comprising the spintronic stack of claim 20.

26. A magnetic sensor comprising the spintronic stack of claim 20.

27. A magnetic recording device comprising the spintronic stack of claim 20.
